(19) United States
(12) Patent Application Publication
(10) Pub. No.: US 2023/0386801 A1
(43) Pub. Date: Nov. 30, 2023

(54) PLASMA PROCESSING APPARATUS

(71) Applicants: Tokyo Electron Limited, Tokyo (JP); Kyoto Institute of Technology, Kyoto-shi, Kyoto (JP)

(72) Inventors: Tsuyoshi Moriya, Tokyo (JP); Haruhiko Himura, Kyoto-shi, Kyoto (JP)

(21) Appl. No.: 18/251,077

(22) PCT Filed: Oct. 19, 2021
(86) PCT No.: PCT/JP2021/038547

§ 371 Date: Apr. 28, 2023

(30) Foreign Application Priority Data
Nov. 2, 2020 (JP) 2020-183641

(51) Int. Cl. H01J 37/32

(52) U.S. Cl. CPC H01J 37/32697; H01J 37/32422; H01J 2237/1207; H01J 2237/04735; H01J 37/3266

(57) ABSTRACT

A plasma processing apparatus includes a processing vessel in which a substrate as a target of a plasma processing is disposed; a plasma forming device configured to form plasma within the processing vessel; a focusing device disposed within the processing vessel, and configured to focus multiple ions in the plasma to output an ion beam; and a sorting device configured to sort out, from the ion beam outputted from the focusing device, a specific ion to be supplied to the substrate.

### TECHNICAL FIELD

The various aspects and embodiments described herein pertain generally to a plasma processing apparatus.

### BACKGROUND

Patent Document 1 describes a technique of reducing damage to a substrate by providing an ion source that is provided outside a processing vessel and configured to sort out and output a specific ion and supplying only the specific ion into the processing vessel, in which a plasma processing on the substrate is performed, from the ion source.

### PRIOR ART DOCUMENT

Patent Document 1: International Publication No. 2019/239613

### DISCLOSURE OF THE INVENTION

### Problems to be Solved by the Invention

Exemplary embodiments provide a technique capable of reducing damage to a substrate while achieving downsizing of an apparatus.

### Means for Solving the Problems

In an exemplary embodiment, a plasma processing apparatus includes a processing vessel in which a substrate as a target of a plasma processing is disposed; a plasma forming device configured to form plasma within the processing vessel; a focusing device disposed within the processing vessel, and configured to focus multiple ions in the plasma to output an ion beam; and a sorting device configured to sort out, from the ion beam outputted from the focusing device, a specific ion to be supplied to the substrate.

### Effect of the Invention

According to the exemplary embodiment, it is possible to reduce damage to the substrate while achieving downsizing of the apparatus.

### BRIEF DESCRIPTION OF THE DRAWINGS

FIG. 1 is a diagram schematically illustrating a plasma processing apparatus according to an exemplary embodiment.

FIG. 2 is a schematic cross sectional view illustrating a configuration of a focusing device and a sorting device according to the exemplary embodiment.

FIG. 3 is a diagram illustrating an example layout of two pairs of magnets according to the exemplary embodiment.

### DETAILED DESCRIPTION

Hereinafter, exemplary embodiments of a plasma processing apparatus according to the present disclosure will be described in detail with reference to the accompanying drawings. In the various drawings, same or corresponding parts will be assigned same reference numerals. Further, it should be noted that the plasma processing apparatus of the present disclosure is not limited by the exemplary embodiments.

In the plasma processing apparatus in which the ion source is provided outside the processing vessel as in the prior art, however, it is difficult to scale down the apparatus although it is possible to reduce the damage to the substrate. Specifically, the ion source includes components, such as a plasma forming source and a pipe connected to the plasma forming source and the processing vessel and provided with an electromagnet capable of generating a magnetic field for sorting out the specific ion. For this reason, in the plasma processing apparatus, a space occupied by these components increases at the outside of the processing vessel. As a result, the plasma processing apparatus including the ion source is scaled up in overall.

In this regard, it is required to reduce the damage to the substrate and, at the same time, to downsize the apparatus.

[Configuration of Plasma Processing Apparatus]

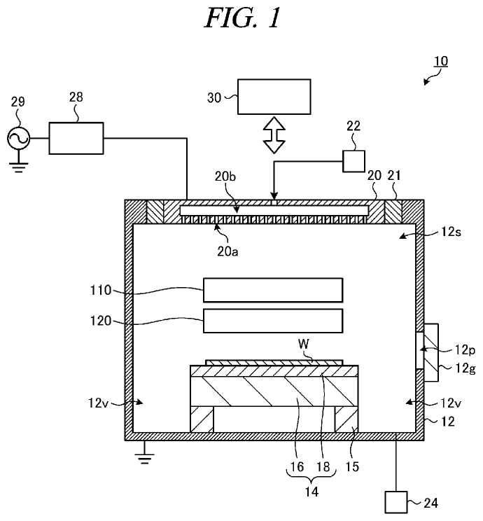

First, a configuration of a plasma processing apparatus 10 according to an exemplary embodiment will be described. FIG. 1 is a diagram schematically illustrating the plasma processing apparatus according to the exemplary embodiment. FIG. 1 shows a structure of the plasma processing apparatus 10 according to the exemplary embodiment on a longitudinal cross section thereof. The plasma processing apparatus 10 shown in FIG. 1 is configured as a capacitively coupled plasma processing apparatus. The plasma processing apparatus 10 is equipped with a processing vessel 12. The processing vessel 12 has a substantially cylindrical shape and extends in a vertical direction. The processing vessel 12 has a substantially cylindrical sidewall and a bottom that is continuous with a lower end of the sidewall. The processing vessel 12 provides an internal space 12s therein. The processing vessel 12 is made of a metal such as aluminum. A plasma -resistant coating is formed on an inner wall surface of the processing vessel 12. The plasma-resistant coating may be a ceramic film such as an alumite film or an yttrium oxide film. The processing vessel 12 is grounded.

A passage 12p through which a substrate W such as a semiconductor wafer is carried in and out is formed at a sidewall of the processing vessel 12. The substrate W passes through the passage 12p when it is transferred from the outside of the processing vessel 12 into the internal space 12s or when it is transferred from the internal space 12s to the outside of the processing vessel 12. The passage 12p is opened or closed by a gate valve 12g, which is provided along the sidewall of the processing vessel 12.

A supporting table 14 is provided in the internal space 12s of the processing vessel 12. The supporting table 14 is configured to place the substrate W on a top surface thereof and to support the substrate W placed thereon. The supporting table 14 is supported by a supporting body 15. The supporting body 15 has insulation property, and extends upwards from the bottom of the processing vessel 12.

The supporting table 14 includes a lower electrode 16. The lower electrode 16 has a substantially disk shape. The lower electrode 16 is made of a conductive material such as aluminum. In the exemplary embodiment, the supporting table 14 further includes an electrostatic chuck 18. The electrostatic chuck 18 is provided on the lower electrode 16. The substrate W is placed on the electrostatic chuck 18. The electrostatic chuck 18 includes a dielectric film and an electrode embedded in the dielectric film. The electrode of the electrostatic chuck 18 may be a film having conductivity. A power source is connected to the electrode of the electrostatic chuck 18 via a switch. When a voltage is applied from the power source to the electrode of the electrostatic chuck 18, an electrostatic attraction force is generated between the electrostatic chuck 18 and the substrate W. The substrate W is attracted to and held by the electrostatic chuck 18 by the generated electrostatic attraction force.

The supporting table 14 is configured to be temperature-controlled. For example, in the supporting table 14, a temperature control mechanism such as a non-illustrated heater is provided inside the lower electrode 16 or the electrostatic chuck 18, so it is possible to control a temperature of a placing surface of the electrostatic chuck 18 on which the substrate W is placed. The substrate W is heated by the supporting table 14.

A shower head 20 is provided above the supporting table 14. A part of the internal space 12s exists between the shower head 20 and the supporting table 14. In the exemplary embodiment, an upper end of the processing vessel 12 is open. The shower head 20 is supported on the upper end of the processing vessel 12 with a member 21 therebetween. The member 21 has insulation property. The shower head 20, together with the member 21, closes the opening of the upper end of the processing vessel 12.

The shower head 20 is formed of one or more components having conductivity, and has a function as an upper electrode with respect to the lower electrode 16. The one or more components constituting the shower head 20 may be formed of a material such as aluminum or silicon. Alternatively, the shower head 20 may be formed of one or more components having conductivity and one or more components having insulation property. A plasma-resistant film may be formed on a surface of the shower head 20.

The shower head 20 is provided with a plurality of gas discharge holes 20a and a gas diffusion space 20b. The plurality of gas discharge holes 20a extend downwards from the gas diffusion space 20b to a bottom surface of the shower head 20 on the internal space 12s side. A gas supply 22 is connected to the gas diffusion space 20b.

The gas supply 22 is configured to supply, for example, various kinds of processing gases for use in film formation or the like to the gas diffusion space 20b. For example, the gas supply 22 has a plurality of gas sources, a plurality of flow rate controllers such as mass flow controllers, and a plurality of valves. Each of the plurality of gas sources is connected to the gas diffusion space 20b via a corresponding one of the plurality of flow rate controllers and a corresponding one of the plurality of valves. The gas supply 22 adjusts a flow rate of a processing gas from a selected gas source among the plurality of gas sources, and supplies the processing gas to the gas diffusion space 20b. The processing gas supplied to the gas diffusion space 20b is introduced into the internal space 12s through the plurality of gas discharge holes 20a.

An exhaust device 24 is connected to the bottom of the processing vessel 12. The exhaust device 24 is configured to communicate with the internal space 12s. The exhaust device 24 has a pressure control device such as a pressure regulating valve, and a vacuum pump such as a turbo molecular pump or a dry pump. By operating the exhaust device 24, a gas existing in the internal space 12s is exhausted through a space 12v between the support table 14 and the sidewall of the processing vessel 12. Further, the pressure within the internal space 12s is adjusted to a preset pressure by the exhaust device 24.

The shower head 20 is connected to a high frequency power supply 29 via a matching circuit 28. When forming plasma, the high frequency power supply 29 is configured to apply a high frequency power of a predetermined frequency to the shower head 20 serving as the upper electrode. In the present exemplary embodiment, the frequency of the high frequency power used for the plasma formation is set to a low excitation frequency of 450 kHz. Here, however, the frequency of the high frequency power used for the plasma formation is not limited to 450 kHz, and a high frequency power having a frequency ranging from 300 kHz to 5 MHz may be used. As the high frequency power is applied from the high frequency power supply 29 to the shower head 20, the plasma is formed from the processing gas in the internal space 12s of the processing vessel 12. The high frequency power supply 29 is an example of a plasma forming device.

In addition, although the exemplary embodiment has been described for the example where the plasma processing apparatus 10 applies the high frequency power to the shower head 20 as the upper electrode to cause a plasma discharge, the exemplary embodiment is not limited thereto. In case of discharging the plasma, a high frequency power may be applied to the lower electrode 16. For example, in the plasma processing apparatus 10, a high frequency power supply may be connected to the lower electrode 16 via a matching device, and a high frequency power of a predetermined frequency may be applied from this high frequency power supply to the lower electrode 16. Further, in case of discharging the plasma, high frequency powers may be applied to both the shower head 20 and the lower electrode 16 individually.

A focusing device 110 and a sorting device 120 are disposed in the processing vessel 12. The focusing device 110 is disposed in a plasma formation region below the shower head 20. The plasma formation region is, as a region forming an upper portion of the internal space 12s of the processing vessel 12, a region in which the plasma is formed as a high frequency energy is applied to the processing gas below the shower head 20. The focusing device 110 is configured to extract a plurality of ions in the plasma formed in the plasma formation region, focus the extracted plurality of ions, and output them as an ion beam. The energy of the outputted ion beam is variable.

The sorting device 120 is disposed between the focusing device 110 and the supporting table 14 (that is, the substrate W on the supporting table 14). The sorting device 120 is configured to sort out a specific ion to be supplied to the substrate W on the supporting table 14 from the ion beam outputted from the focusing device 110. This specific ion is an ion with uniform energy and high chemical reactivity. As an example of the specific ion, a negative ion of oxygen, a negative ion of hydrogen, or the like may be mentioned. The negative ion of oxygen is also called “oxygen anion radical”. The negative ion of hydrogen is also referred to as “hydride.”

In this configuration, the plurality of ions in the plasma formed within the processing vessel 12 are focused by the focusing device 110 to form the ion beam, and is then incident to the sorting device 120. Then, the specific ion is sorted out from the ion beam by the sorting device 120 and supplied to the substrate W on the supporting table 14. Accordingly, a particle supplied to the substrate W is limited to the specific ion having the uniform energy and the high chemical reactivity, and a particle other than the specific ion is suppressed from reaching the substrate W. As a result, the damage to the substrate W can be reduced. In addition, since the focusing device 110 and the sorting device 120 are disposed within the processing vessel 12, components such as a plasm forming source, a pipe provided with an electromagnet for sorting out a specific ion, and so forth need not be provided outside the processing vessel 12. Therefore, the space occupied by the components at the outside of the processing vessel 12 can be reduced, and, as a result, the plasma processing apparatus 10 can be reduced in size.

The operation of the plasma processing apparatus 10 configured as described above is controlled by the controller 30 in overall. The controller 30 is, for example, a computer, and includes a CPU (Central Processing Unit), a RAM (Random Access Memory), a ROM (Read Only Memory), an auxiliary storage device, and the like. The CPU is operated to control the operation of the entire apparatus based on a program stored in the ROM or the auxiliary storage device, or process conditions for film formation. By way of example, the controller 30 controls the start and stop of the supply of each gas, the flow rate of each gas, the carry-in/carry-out of the substrate W, the temperature of the non-illustrated heater of the supporting table 14, the pressure within the processing vessel 12, and the supply and the stop of the supply of the high frequency power from the high frequency power supply 29. Furthermore, a computer-readable program required for the control may be stored in a recording medium. The recording medium may be, by way of non-limiting example, a flexible disk, a CD (Compact Disc), a CD-ROM, a hard disk, a flash memory, or a DVD. In addition, the controller 30 may be provided inside or outside the plasma processing apparatus 10. When the controller 30 is provided at the outside of the plasma processing apparatus 10, the controller 30 may control the plasma processing apparatus 10 via a wired or wireless device of communication.

[Configuration of Focusing Device and Sorting Device]

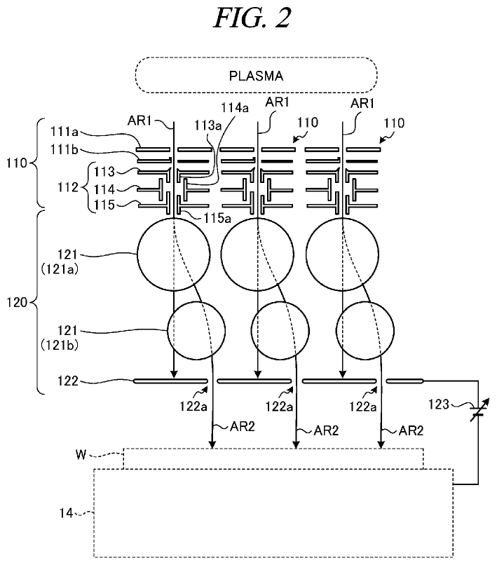

Now, referring to FIG. 2, the configuration of the focusing device 110 and the sorting device 120 will be further described. FIG. 2 is a schematic cross sectional view showing the configuration of the focusing device and the sorting device according to the exemplary embodiment.

The focusing device 110 is disposed in the plasma formation region below the shower head 20, and serves to output the ion beam by focusing the plurality of ions in the plasma formed in the plasma formation region. The focusing device 110 has electrodes 111a and 111b and an Einzel lens 112.

The electrodes 111a and 111b are disposed to face each other. A through hole is formed in the center of each of the electrodes 111a and 111b. A potential difference is applied to the electrodes 111a and 111b. The electrodes 111a and 111b attract the plurality of ions in the plasma into the through holes and accelerate the attracted ions based on the potential difference.

The Einzel lens 112 focuses the accelerated ions based on an electromagnetic field. The Einzel lens 112 has lens elements 113 to 115 arranged along a traveling direction of the accelerated ions. The lens elements 113 to 115 are respectively provided with cylindrical openings 113a to 115a through which the plurality of ions can pass. From the viewpoint of downsizing the Einzel lens 112, the lens elements 113 to 115 are arranged such that the openings 113a to 115a are partially overlapped along the traveling direction of the plurality of ions. The lens elements 113 to 115 generate an electromagnetic field when the lens elements 113 and 115 located on both sides of the lens element 114 are grounded and a positive voltage is applied to the lens element 114. The Einzel lens 112 attracts the accelerated ions into the openings 113a to 115a of the lens elements 113 to 115, applies an electromagnetic force by the electromagnetic field to the attracted ions to focus them, and outputs the obtained ion beam. In FIG. 2, the traveling direction of the plurality of ions outputted as the ion beam from the focusing device 110 is indicated by an arrow AR1.

The sorting device 120 is disposed between the focusing device 110 and the supporting table 14 (that is, the substrate W on the supporting table 14), and serves to sort out, from the ion beam outputted from the focusing device 110, a specific ion to be supplied to the substrate W. The sorting device 120 has a pair of magnets 121a (only one magnet 121a is shown in FIG. 2), a pair of magnets 121b (only one magnet 121b is shown in FIG. 2), and a blocking member 122.

The pair of magnets 121a are disposed at positions with the ion beam outputted from the focusing device 110 therebetween, and generate a magnetic field that changes a traveling direction of the specific ion among the plurality of ions included in the ion beam. The pair of magnets 121b are disposed at positions with the ion beam outputted from the focusing device 110 therebetween, and generate a magnetic field that further changes the traveling direction of the specific ion, which has been changed by the magnetic field of the pair of magnets 121a. Hereinafter, the pair of magnets 121a and the pair of magnets 121b will be appropriately referred to as “two pairs of magnets 121”.

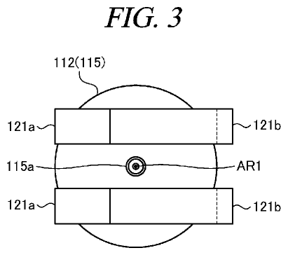

FIG. 3 is a diagram showing an example layout of the two pairs of magnets 121 according to the exemplary embodiment. FIG. 3 illustrates the Einzel lens 112 of the focusing device 110 seen from below, and it shows the positions where the magnets 121a and 121b are provided. Each of the lens elements (lens elements 113 to 115) of the Einzel lens 112 has a disk shape. FIG. 3 shows the lens element 115 located at the bottommost position among the lens elements 113 to 115. Formed at the center of the lens element 115 is the cylindrical opening 115a. The pair of magnets 121a are provided at the positions with the center position of the lens element 115 (that is, the position of the opening 115a) therebetween. In addition, the pair of magnets 121b are provided at the positions with the center position of the lens element 115 (that is, the position of the opening 115a) therebetween, which are shifted sideways from the pair of magnets 121a along a bottom surface of the lens element 115. The positions of the magnets 121a and 121b shown in FIG. 3 correspond to the positions where they are arranged with the ion beam outputted from the focusing device 110 therebetween.

Reference is made back to FIG. 2. The pair of magnets 121a and the pair of magnets 121b are formed in a disc shape and have different diameters. The pair of magnets 121a and the pair of magnets 121b generate the magnetic fields in opposite directions. By way of example, the pair of magnets 121agenerate the magnetic field directed from the inside to the front side of FIG. 2, and the pair of magnets 121b generate the magnetic field directed from the front side to the inside of FIG. 2. The strength of the magnetic field generated by the pair of magnets 121a and the strength of the magnetic field generated by the pair of magnets 121b depend on the shapes and the diameters of the pair of magnets 121a and 121b. The specific ion included in the ion beam outputted from the focusing device 110 is given a force in a direction away from the traveling direction of the ion beam (the direction of the arrow AR1) by the magnetic field generated by the pair of magnets 121a, and travels toward the pair of magnets 121b. The specific ion traveling toward the pair of magnets 121b is given a force in a direction closer to the traveling direction of the ion beam (the direction of the arrow AR1) by the magnetic field generated by the pair of magnets 121b, and travels toward the substrate W on the supporting table 14. In FIG. 2, the traveling direction of the specific ion is indicated by an arrow AR2 diverging from the arrow AR1.

Further, the shapes and the sizes of the pair of magnets 121a and the pair of magnets 121b shown in FIG. 2 is just an example, and the exemplary embodiment is not limited thereto. The sizes and the shapes may be changed depending on the strength of the magnetic field required to sort out the specific ion. For example, each of the pair of magnets 121a and the pair of magnets 121b may be formed in a shape other than the disk shape. In addition, the pair of magnets 121a and the pair of magnets 121b may have the same size.

As the pair of magnets 121a and the pair of magnets 121b, permanent magnets may be used or electromagnets including a coil may be used.

The blocking member 122 is disposed below the two pairs of magnets 121 to allow the specific ion whose traveling direction is changed by the magnetic fields of the two pairs of magnets 121 to pass therethrough while blocking ions other than the specific ion. The blocking member 122 is formed in a plate shape, and has holes 122a through which the specific ion can pass. The specific ion whose traveling direction is changed to the direction of the arrow AR2 by the magnetic fields of the two pairs of magnets 121 passes through the holes 122a and is supplied to the substrate W. On the other hand, other ions, whose traveling direction is not changed by the magnetic fields of the two pairs of magnets 121, travel in the direction of the arrow AR1 as the ion beam to be absorbed by a plate surface of the blocking member 122.

Further, the blocking member 122 and the supporting table 14 are connected to a variable DC power supply 123. The variable DC power supply 123 is configured to apply a potential difference between the blocking member 122 and the supporting table 14, thus decelerating the specific ion to be supplied to the substrate W through the holes 122a of the blocking member 122. Since the specific ion to be supplied to the substrate W is decelerated, damage to the substrate W that might be caused by collision with high-speed ions can be reduced.

In the plasma processing apparatus 10 according to the present exemplary embodiment, multiple sets of the focusing device 110 and the two pairs of magnets 121 are disposed. In the present exemplary embodiment, nine sets of the focusing device 110 and the two pairs of magnets 121 are arranged above the supporting table 14 (that is, the substrate W on the supporting table 14) within the processing vessel 12 in a 3×3 matrix shape along a top surface of the supporting table 14. FIG. 2 shows three sets out of the nine sets of the focusing device 110 and the two pairs of magnets 121. The positions of the sets of the focusing device 110 and the two pairs of magnets 121 shown in FIG. 2 is just an example, and the present exemplary embodiment is not limited thereto. By way of example, the multiple sets of the focusing device 110 and the two pairs of magnets 121 may be arranged in concentric circles having different radii around a central axis of the supporting table 14.

The blocking member 122 has, at a position corresponding to each set of the focusing device 110 and the two pairs of magnets 121, the hole 122a through which the specific ion can pass. In the present exemplary embodiment, since the nine sets of the focusing device 110 and the two pairs of magnets 121 are disposed, the blocking member 122 has nine holes 122a respectively corresponding to the positions of the nine sets. With this configuration, the specific ions can be supplied to required positions on the substrate W, and, as a result, the processing precision of the substrate W can be improved.

[Effects]

As described above, the plasma processing apparatus 10 according to the exemplary embodiment includes the processing vessel 12, the high frequency power supply 29 (plasma forming device), the focusing device 110, and the sorting device 120. The processing vessel 12 accommodates therein the substrate W as a target of a plasma processing. The high frequency power supply 29 forms the plasma within the processing vessel 12. The focusing device 110 is disposed in the processing vessel 12 and outputs the ion beam by focusing the plurality of ions in the plasma. The sorting device 120 sorts out the specific ion to be supplied to the substrate W from the ion beam outputted from the focusing device 110. Accordingly, the plasma processing apparatus 10 is capable of restricting the particle to be supplied to the substrate W to, for example, the specific ion having the low energy and the high chemical reactivity, so that damage to the substrate W can be reduced. Additionally, in the plasma processing apparatus 10, since the focusing device 110 and the sorting device 120 are disposed in the processing vessel 12, the space occupied by components outside the processing vessel 12 can be reduced, so that downsizing of the apparatus can be achieved.

Furthermore, in the plasma processing apparatus 10, the focusing device 110 has the electrodes 111a and 111b (a plurality of electrodes) and the Einzel lens 112. The electrodes 111a and 111b accelerate the plurality of ions in the plasma based on the potential difference. The Einzel lens 112 focuses the plurality of accelerated ions based on the electromagnetic field. As a result, the plasma processing apparatus 10 is capable of efficiently obtain the ion beam by focusing only the ions that are charged particles.

Further, in the plasma processing apparatus 10, the sorting device 120 includes the two pairs of magnets 121 and the blocking member 122. The two pairs of magnets 121 are provided at the positions with the ion beam outputted from the focusing device 110 therebetween, and generate the magnetic field that changes the traveling direction of a specific ion among the plurality of ions included in the ion beam. The blocking member 122 allows the specific ion whose traveling direction has been changed by the magnetic fields of the two pairs of magnets 121 to pass therethrough while blocking ions other than the specific ion. With this configuration, the plasma processing apparatus 10 is capable of supplying the specific ion to the substrate W with high purity without allowing the ions other than the specific ion to reach the substrate W. As a result, damage to the substrate W that might be caused by the ions other than the specific ion can be reduced.

Furthermore, in the plasma processing apparatus 10, the multiple sets of the focusing device 110 and the two pairs of magnets 121 are disposed above the substrate W in the processing vessel 12. At the position corresponding to each set of the focusing device 110 and the two pairs of magnets 121, the blocking member 122 has the hole 122a through which the specific ion can pass. With this configuration, the plasma processing apparatus 10 is capable of supplying the specific ions to required positions on the substrate W, and, as a result, the processing precision of the substrate W can be improved.

So far, the exemplary embodiment has been described. However, it should be noted that the above-described exemplary embodiment is illustrative in all aspects and is not anyway limiting. In fact, the above-described exemplary embodiment can be embodied in various forms. Further, the above-described exemplary embodiment may be omitted, replaced and modified in various ways without departing from the scope and the spirit of claims.

By way of example, although the above-described plasma processing apparatus 10 is configured as the capacitively coupled plasma processing apparatus, the present disclosure may be applicable to any plasma processing apparatus. For example, the plasma processing apparatus 10 may be any of various types of plasma processing apparatuses, such as an inductively coupled plasma processing apparatus, a plasma processing apparatus configured to excite a gas by a surface wave such as a microwave, and so forth.

Further, although the exemplary embodiment has been described for the example where the plasma processing apparatus 10 changes the traveling direction of the specific ion by using the two pairs of magnets 121 (the pair of magnets 121a and the pair of magnets 121b), the present disclosure may not be limited thereto. For example, the pair of magnets 121b may be omitted, and the traveling direction of the specific ion may be changed by using only the single pair of magnets 121a. In this case, the focusing device 110 is obliquely arranged so that the ion beam is obliquely incident to the pair of magnets 121a, thus allowing the traveling direction of the specific ion included in the ion beam to be changed by the magnetic field of the pair of magnets 121a to a direction closer to the substrate W. Moreover, three or more pairs of magnets may be used to change the traveling direction of the specific ion. In short, the traveling direction of the specific ion is changed by using at least one pair of magnets.

Additionally, although the above exemplary embodiment has been described for the example case of using the Einzel lens 112 in which the three lens elements (the lens elements 113 to 115) are arranged, the number of the lens elements included in the Einzel lens 112 is not limited to three. By way of example, an Einzel lens may be formed by arranging an odd number of lens elements of 5 or more.

### EXPLANATION OF CODES

10: Plasma processing apparatus
12: Processing vessel
29: High frequency power
110: Focusing device
111a, 111b: Electrode
112: Einzel lens
120: Sorting device
121, 121a, 121b: Magnet
122: Blocking member
122a: Hole

1. A plasma processing apparatus, comprising:
a processing vessel in which a substrate as a target of a plasma processing is disposed;
a plasma forming device configured to form plasma within the processing vessel;
a focusing device disposed within the processing vessel, and configured to focus multiple ions in the plasma to output an ion beam; and
a sorting device configured to sort out, from the ion beam outputted from the focusing device, a specific ion to be supplied to the substrate.

2. The plasma processing apparatus of claim 1,
wherein the focusing device comprises:
multiple electrodes configured to accelerate the multiple ions in the plasma based on a potential difference; and
an Einzel lens configured to focus the accelerated multiple ions based on an electromagnetic field.

3. The plasma processing apparatus of claim 1,
wherein the sorting device comprises:
at least one pair of magnets provided at positions with the ion beam outputted from the focusing device therebetween, and configured to generate a magnetic field configured to change a traveling direction of the specific ion among the multiple ions included in the ion beam; and
a blocking member configured to allow the specific ion whose traveling direction is changed by the magnetic field of the at least one pair of magnets to pass through while blocking ions other than the specific ion.

4. The plasma processing apparatus of claim 3,
wherein multiple sets of the focusing device and the at least one pair of magnets are disposed above the substrate within the processing vessel, and
the blocking member has, at a position corresponding to each set of the focusing device and the at least one pair of magnets, a hole through which the specific ion passes.
